(19) United States
(12) Patent Application Publication
(10) Pub. No.: US 2020/0082789 A1
(43) Pub. Date: Mar. 12, 2020

(54) DISPLAY DEVICE AND METHOD FOR AUTOMATICALLY REGULATING SCREEN BRIGHTNESS OF THE SAME

(71) Applicants: Chongqing HKC Optoelectronics Technology Co., Ltd., Chongqing (CN); HKC CORPORATION LIMITED, Shenzhen (CN)

(72) Inventors: Kaijun Liu, Chongqing (CN); Entsung Cho, Chongqing (CN)

(21) Appl. No.: 16/311,517

(22) PCT Filed: Oct. 24, 2018
(86) PCT No.: PCT/CN2018/111642

§ 371 Date: Dec. 19, 2018

(30) Foreign Application Priority Data
Sep. 12, 2018 (CN) 201811060502.8

(51) Int. Cl. G09G 5/10; H01L 31/14; H01L 31/0216; H01L 31/113; G09G 3/36

(52) U.S. Cl. CPC G09G 5/10; H01L 31/145; H01L 31/02164; G09G 2320/0626; G09G 3/3648; G09G 2360/144; G09G 2360/145; H01L 31/1136

(57) ABSTRACT

A display device, including a control assembly, a display panel having a display area and a non-display area, a first switch optical sensor disposed at the display area, and a second switch optical sensor disposed at the non-display area.

### CROSS-REFERENCE TO RELATED APPLICATION

The present application is a national stage of and claims priority of International patent serial no. PCT/CN2018/111642, filed Oct. 24, 2018.

### BACKGROUND OF THE INVENTION

### Field of the Invention

The present application relates to the technical field of display manufacture, and more specifically to a display device and a method for automatically regulating screen brightness of the display device.

### Description of Related Art

It is well known that as a display tool that displays certain electronic files on the screen via a specific transmission equipment and then reflects them to the human eyes, a display has been deeply integrated into daily life of people and become an indispensable part of production and daily life of people. In addition, the thin film transistor (TFT) means that each liquid crystal pixel on the liquid crystal display is driven by a thin film transistor integrated at the rear thereof. The thin film transistor-Liquid crystal display (TFT-LCD) is considered to be one of the best LCD color displays, because of the advantages of high responsiveness, high brightness, high contrast, and mature manufacturing process. And the thin film transistor-liquid crystal display is served as mainstream display devices for all kinds of laptops and desktops.

With the advancement of technology, the quality and display effect of display has become better and better. In order to save energy and reduce the eye irritation caused by the display changing with the environment, most of the displays carried by mobile phones, IPADs, etc. are equipped with photoreceptors to control the backlight brightness of the display to change with the environment. Correspondingly, a medium-sized or a large-sized display capable of automatically regulating brightness are generally equipped with optical sensors, and these optical sensors are basically used to collect light intensity data of external environment. However, the solution is still not ideal for energy saving and vision protection.

### Technical Problems

An object of the embodiment of the present application is to provide a display device and a method for automatically regulating screen brightness of the display device, to solve the technical problem that automatically regulating screen brightness of the display device is not effectively, and unable to overcome energy waste and vision loss.

### Technical Solutions

In order to solve the above technical problem, the technical solution adopted in embodiments of the present application are as follows:

Embodiments of the present application provide a display device, the display device includes a control assembly and a display panel having a display area and a non-display area; the display device further includes:

a first switch optical sensor, disposed at the non-display area of the display panel and configured to convert an environmental light intensity into a first electrical signal; and

a second switch optical sensor, disposed at the display area of the display panel and configured to convert a light intensity inside the display and the environmental light intensity into a second electrical signal;

in which, the control assembly automatically regulates a display brightness of the display panel according to the first electrical signal and a difference between the second electrical signal and the first electrical signal.

In an embodiment, the display device further includes a signal processor configured to receive, process, and feed back the first electrical signal and the second electrical signal.

In an embodiment, the display panel includes a black matrix, and the black matrix defines therein avoidance notches corresponding to light sensing portions of the first switch optical sensor and the second switch optical sensor.

In an embodiment, the first switch optical sensor and the second switch optical sensor are manufactured by a four-layer mask process.

In an embodiment, the display device further includes a drive circuit board electrically connected to the control assembly; the first switching optical sensor and the second switching optical sensor each includes:

a channel layer, which is light sensitive and configured to collect light intensity and to generate a photoconductive current;

a source electrode, connected to the drive circuit board and disposed above the channel layer; and

a drain electrode, connected to the drive circuit board and disposed above the channel layer;

the channel layer forms therein a conductive channel corresponding to a portion between the source electrode and the drain electrode; the first switch optical sensor and the second switch optical sensor are electrically connected to the drive circuit board.

In an embodiment, the first switch optical sensor and the second switch optical sensor further each includes:

a substrate;

a switch gate electrode, disposed at the substrate; and,

an insulation layer, disposed at the substrate and configured to protect the switch gate electrode and to separate the channel layer from the switch gate electrode.

In an embodiment, the first switch optical sensor and the second switch optical sensor further each includes:

a doped layer, disposed above the channel layer and configured to reduce contact resistances between the channel layer and the source electrode and between the channel layer and the drain electrode.

In an embodiment, the insulation layer is provided with a protection layer;

the protection layer surrounds the channel layer, the doped layer, the source electrode, and the drain electrode from peripheries thereof, and the protection layer is provided with an opening configured to adapt to the conductive channel.

Embodiments of the present application further provide a display device, and the display device includes:

a display panel, having a display area and a non-display area;

a first switch optical sensor, disposed at the non-display area of the display panel and configured to convert an environmental light intensity into a first electrical signal;

a second switch optical sensor, disposed at the display area of the display panel and configured to convert a light intensity inside the display and the environmental light intensity into a second electrical signal;

a signal processor, configured to receive, process, and feed back the first electrical signal and the second electrical signal;

a control assembly, automatically regulating a display brightness of the display panel according to the first electrical signal and a difference between the second electrical signal and the first electrical signal;

the display device further includes:

a drive circuit board, electrically connected to the control assembly;

the first switch optical sensor and the second switch optical sensor each includes:

a channel layer, which is light sensitive and configured to collect light intensity and generate a photoconductive current;

a source electrode, connected to the drive circuit board and disposed above the channel layer; and

a drain electrode, connected to the drive circuit board and disposed above the channel layer;

the channel layer forms therein a conductive channel corresponding to a portion between the source electrode and the drain electrode; the first switch optical sensor and the second switch optical sensor are electrically connected to the drive circuit board.

In an embodiment, the first switch optical sensor and the second switch optical sensor further each includes:

a substrate;

a switch gate electrode, disposed at the substrate; and,

an insulation layer, disposed at the substrate and configured to protect the switch gate electrode and to separate the channel layer from the switch gate electrode.

In an embodiment, the first switch optical sensor and the second switch optical sensor further each include:

a doped layer, disposed above the channel layer and configured to reduce contact resistances between the channel layer and the source electrode and between the channel layer and the drain electrode.

In an embodiment, the insulation layer is provided with a protection layer;

the protection layer surrounds the channel layer, the doped layer, the source electrode, and the drain electrode from peripheries thereof; the protection layer is provided with an opening configured to adapt to the conductive channel.

In an embodiment, the first switch optical sensor and the second switch optical sensor are thin film transistor devices.

The embodiments of the present application further provide a method for automatically regulating screen brightness of a display device, in which the display device includes:

a control assembly;

a display panel, having a display area and a non-display area;

a first switch optical sensor, disposed at the non-display area of the display panel;

a second switch optical sensor, disposed at the display area of the display panel;

the method includes:

converting an environmental light intensity into a first electrical signal via the first switch optical sensor, and converting a light intensity inside the display and the environmental light intensity into a second electrical signal via the second switch optical sensor;

calculating a difference between the second electrical signal and the first electrical signal;

automatically regulating a display brightness of the display panel according to the first electrical signal and the difference.

In an embodiment, the display device further includes a signal processor; and the step of calculating a difference between the second electrical signal and the first electrical signal includes:

respectively receiving the first electrical signal and the second electrical signal via the signal processor; and

calculating the difference between the second electrical signal and the first electrical signal.

In an embodiment, the display panel includes a black matrix, and the black matrix defines therein avoidance notches corresponding to a light sensing portions of the first switch optical sensor and the second switch optical sensor.

In an embodiment, the first switch optical sensor and the second switch optical sensor are thin film transistor devices.

### Beneficial Effects

The embodiments of the present application provide a display device and a method for automatically regulating screen brightness of the display device, the first switch optical sensor is adopted to convert an environmental light intensity into a first electrical signal, and the second switch optical sensor is adopted to convert inside light intensity of the display and environmental light intensity into a second electrical signal, in which the control assembly can automatically regulate the display brightness of the display panel according to the first electrical signal and the difference between the first electrical signal and the second electrical signal and the first electrical signal. In this way, the present application uses two switch optical sensors(such as two thin film transistor devices) as optical sensors to simultaneously monitor the environmental light intensity and the light intensity of the display itself, thereby the brightness of the display can be more accurately and automatically regulated, and the display being displayed is avoided being too bright or too dark and causing the problem of energy waste and affecting vision.

### BRIEF DESCRIPTION OF THE DRAWINGS

In order to explain the embodiments of the present application more clearly, a brief introduction regarding the accompanying drawings that need to be used for describing the embodiments of the present application or the prior art is given below; it is obvious that the accompanying drawings described as follows are only some embodiments of the present application, for those skilled in the art, other drawings can also be obtained according to the current drawings on the premise of paying no creative labor.

FIG. 1 is a schematic diagram showing a mounting structure of two switch optical sensors in a display device according to an embodiment of the present application;

FIG. 2 is a schematic diagram showing an electrical connection structure of two switch optical sensors in a display device according to an embodiment of the present application;

FIG. 3 is a flow chart of a method for automatically regulating screen brightness of a display device in an embodiment of the present application.

The reference numerals are listed and referred to as follows:

100—display panel;

200—first switch optical sensor/first thin film transistor device,

210—substrate,

220—switch gate electrode,

230—insulation layer,

240—channel layer,

250—doped layer,

260—source electrode,

270—drain electrode,

280—protection layer,

290—transparent conducting layer;

300—second switch optical sensor/second thin film transistor device,

400—conductive channel,

500—light beam;

600—drive circuit board.

### DETAILED DESCRIPTION OF THE EMBODIMENTS

In order to make the purpose, the technical solution and the advantages of the present application be clearer and more understandable, the present application will be further described in detail below with reference to accompanying figures and embodiments. It should be understood that the specific embodiments described herein are merely intended to illustrate but not to limit the present application.

It is noted that when a component is referred to as being “fixed to” or “disposed at” another component, it can be directly or indirectly on another component. When a component is referred to as being “connected to” another component, it can be directly or indirectly connected to another component. Directions or location relationships indicated by terms such as “length”, “width”, “up”, “down”, “front”, “rear”, “left”, “right”, “vertical”, “horizontal”, “top”, “bottom”, “inside”, “outside”, and so on are the directions or location relationships shown in the accompanying figures, which are only intended to describe the present application conveniently and simplify the description, but not to indicate or imply that an indicated device or component must have specific locations or be constructed and manipulated according to specific locations; therefore, these terms shouldn't be considered as any limitation to the present application. Terms “the first” and “the second” are only used in describe purposes, and should not be considered as indicating or implying any relative importance, or impliedly indicating the number of indicated technical features. As such, technical feature(s) restricted by “the first” or “the second” can explicitly or impliedly comprise one or more such technical feature(s). In the description of the present application, “a plurality of” means two or more, unless there is additional explicit and specific limitation.

In order to make the purpose, the technical solution and the advantages of the present invention be clearer and more understandable, herein, the present application is further described in detail below with reference to accompanying figures and embodiments.

It should be noted that the display device may be a medium-sized or a large-sized display device such as a television or a computer. Specifically, in this embodiment, the display device may be a liquid crystal display based on the TFT, and may also be other suitable display devices.

In general, the display device has a plurality of switch devices, which are specifically a thin film transistor device (ie, a TFT device), a part of the TFT devices can act as switch devices configured to control the bright and dark of each pixel, and another part of the TFT devices, such as a first switch optical sensor 200 and a second switch optical sensor 300, are mainly used as optical sensors to simultaneously monitor an environmental light intensity and a light intensity inside the display (that is, the light intensity of the display itself), and to feed back the results of the monitoring to the control assembly of the display to automatically regulate the light intensity of the display. Therefore, by overcoming the technical bias that people seldom considers to install optical sensors on a medium-sized or a large-sized displays, such as televisions, computers, etc., and people considers that there is no influence whether with or without optical sensors, since the medium-sized or the large-sized displays are mainly used indoors, the display device is provided with two switch optical sensors, and the influence factor of the light intensity inside the display is introduced, a plurality of influence factors are referred to more accurately regulate the brightness of the display, thereby the environmental light intensity and light intensity of the display itself are effectively ensured to reach a balanced status, and the display screen is prevented form too bright when the environmental light intensity is too weak, or the display screen is prevented form too dark and resulting in situation of waste of energy and visual impact, when light intensity of environment is too strong. In addition, since the TFT device is directly used as the optical sensor without additionally mounting the photoreceptor on the display, the manufacturing cost of the display device is lower.

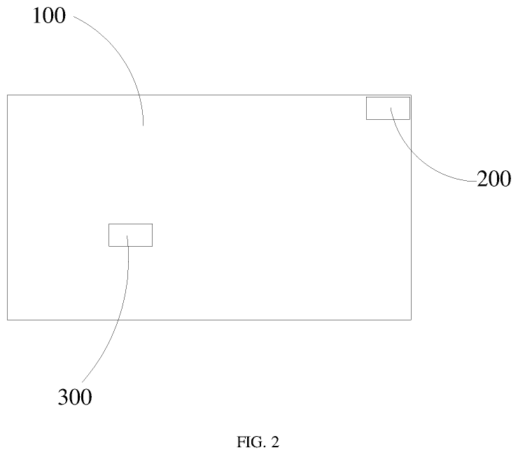

The display device includes a control assembly (not shown) and a display panel 100. The display panel 100 has a display area (not shown) and a non-display area (not shown). The control assembly is mainly configured to control the display brightness of the display panel 100 and the like. As shown in FIG. 2, the display device further includes a first switch optical sensor 200 and a second switch optical sensor 300. Specifically, the first switch optical sensor 200 is disposed at the non-display area of the display panel 100 and mainly configured to convert the environmental light intensity into the first electrical signal. That is, since the non-display area is very weakly affected by the brightness of the display, the first switch optical sensor 200 is mainly configured to collect the light intensity signal of the light beam 500 of environmental and convert the light intensity signal into an electrical signal.

Correspondingly, the second switch optical sensor 300 is disposed at the display area of the display panel 100, and is mainly configured to convert the light intensity inside the display and the environmental light intensity into a second electrical signal. That is, the second switch optical sensor 300 can not only collect the light intensity signal of the light beam 500 of environmental, and considers the problem that the brightness of the display itself will gradually decrease with the increase of the use time, the second switch optical sensor 300 can also collect the light intensity signal of the display itself. It can be understood that there is a signal difference between the second electrical signal and the first electrical signal, and the signal difference is an electrical signal value corresponding to the light intensity inside the display.

In this embodiment, the control assembly (not shown) can automatically regulate the display brightness of the display panel 100 according to the first electrical signal and the difference between the second electrical signal and the first electrical signal. It can be understood that the first switch optical sensor 200 and the second switch optical sensor 300 are both used as optical sensors, and are configured to simultaneously monitor the environmental light intensity and the light intensity inside the display, and by ensuring that the environmental light intensity and the light intensity inside the display maintain a balanced status, and the problem is that one of them is too dark or too bright to cause excessive energy consumption and affecting vision.

It should be noted that, in this embodiment, as shown in FIG. 2, the non-display area is an edge portion of the display panel 100, and the display area is a middle portion of the display panel 100, and generally, the display area is surrounded by the non-display area. In practice, the positional relationship between the non-display area and the display area is not limited to this.

In an embodiment, for ease of operation, the display device generally further includes a signal processor (not shown). The signal processor is mainly configured to receive, process, and feed back the first electrical signal and the second electrical signal. Specifically, after receiving the first electrical signal and the second electrical signal, the signal processor compares and analyzes the second electrical signal and the first electrical signal, and calculates the difference therebetween, and then the first electrical signal and the difference are fed back to control assembly of the liquid crystal display.

In an embodiment, the display panel includes a black matrix (not shown), wherein the black matrix defines therein avoidance notches (not shown) corresponding to the light sensing portions of the first switch optical sensor 200 and the second switch optical sensor 300. That is to say, the first switch optical sensor 200 and the second switch optical sensor 300 are TFT switch devices that do not need to be shielded by the black matrix. It should be noted that, in this embodiment, the display device actually includes a TFT device that can be configured to control the bright and dark of each pixel, which is shielded by the black matrix. It can be understood that, in the present application, it is no need to separately mount the photoreceptor, and the TFT device is directly used to manufacture the photosensitive “TFT switch device”, thereby saving cost.

In an embodiment, the first switch optical sensor 200 and the second switch optical sensor 300 are manufactured by a four layer mask (commonly known as 4Mask). In this way, by reducing one photolithography process, not only is the production cost saved, but also the processing time of the TFT device can be shortened, and the productivity and market competitiveness can be improved.

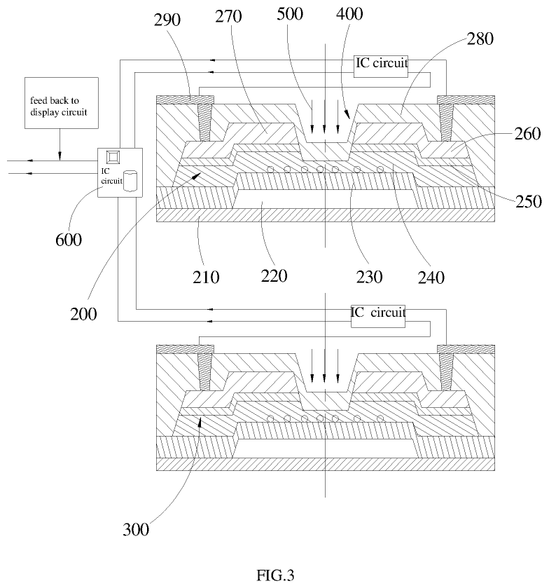

In an embodiment, as shown in FIG. 3, the display device further includes a drive circuit board 600, the drive circuit board 600 is electrically connected to the control assembly (not shown). In addition, as shown in FIG. 3, the first switch optical sensor 200 and the second switch optical sensor 300 each includes: a channel layer 240, a source electrode 260, and a drain electrode 270. The channel layer 240 is light sensitive; the source electrode 260 and the drain electrode 270 are not in contact with each other and are connected to the drive circuit board 600, the source electrode 260 and the drain electrode 270 are both disposed above the channel layer 240. Thus, a portion of the channel layer 240 between the source electrode 260 and the drain electrode 270 forms therein a conductive channel 400. It should be noted that, the conductive channels 400 of the first switch optical sensor 200 and the second switch optical sensor 300 are not shielded by the Black Matrix (BM), so that the light intensity of the light beam 500 can be conveniently collected, thereby generating a photoconductive current. In other words, in the present embodiment, by not using BM being shielded on the conductive channel 400, it is possible to ensure that the thin film transistor device is modified into a “TFT switch device” which can act as a optical sensor.

In addition, both the first switch optical sensor 200 and the second switch optical sensor 300 are electrically connected to the drive circuit board 600. It can be understood that the light beam 500 of environmental or the light beam 500 inside the display entering the conductive channel 400 will be collected by the channel layer 240, and the channel layer 240 can generate a photoconductive current according to the light intensity of the collected light beam 500, and can also conduct the photoconductive current to the drive circuit board 600 via the source electrode 260 and the drain electrode 270. Thus, taking the first switch optical sensor 200 as an example, people can judge the environmental light intensity according to the magnitude of the photoconductive current, and the control assembly of the display device can regulate the brightness of the display screen by changing the output power of the backlight module to save energy and protect the human eyes. It will be appreciated that, in order to increase the collection capability of the light beam 500, or to enhance the light sensitivity of the channel layer 240, the length of the conductive channel 400 is generally increased, such as to 7.5 μm.

In an embodiment, as shown in FIG. 3, in the embodiment, the first switch optical sensor 200 and the second switch optical sensor 300 each further includes: a substrate 210, a switch gate electrode 220 disposed at the substrate 210, and a insulation layer 230 disposed at the substrate 210; the insulation layer 230 is mainly configured to protect the switch gate electrode 220 and to separate the channel layer 240 and the switch gate electrode 220. Specifically, as shown in FIG. 3, two ends of the insulation layer 230 are located between the channel layer 240 and the substrate 210, and the middle portion of the insulation layer 230 is located between the channel layer 240 and the switch gate electrode 220, so that the structure is simpler and more compact.

In addition, in the present embodiment, it should be noted that, the substrate 210 is generally a glass substrate, it may be a substrate of another suitable material. The insulation layer 230 generally adopts a gate insulation layer.

In an embodiment, as shown in FIG. 3, both the first switch optical sensor 200 and the second switch optical sensor 300 each further includes a doped layer 250, the doped layer 250 is disposed above the channel layer 240. In this way, when the photoconductive current is conducted, the contact resistance between the channel layer 240 and the source electrode 260, and between the channel layer 240 and the drain electrode 270 can be reduced by the doped layer 250, thereby ensuring the conduction of the photoconductive current is smooth, and the electrical signal received by the drive circuit board 600 is more precise, which facilitates subsequent regulation of the brightness of the screen more accurately.

In an embodiment, as shown in FIG. 3, a protection layer 280 is disposed at the insulation layer 230. The protection layer 280 surrounds the channel layer 240, the doped layer 250, the source electrode 260, and the drain electrode 270 from the peripheries thereof to correspondingly protect the layers and the electrodes, and the protection layer 280 is provided with an opening adapted to the conductive channel 400 to protect the conductive channel 400. In general, the protection layer 280 has a structure with a shape of [symbol] (a Chinese character“ao”). In addition, in particular, in this embodiment, the protection layer 280 is generally an insulating protection layer, that is, the protection layer 280 is generally manufactured an insulating material or adopts other means to achieve an insulating effect.

It should be noted that, as shown in FIG. 3, the first switch optical sensor 200 and the second switch optical sensor 300 each further includes a transparent conducting layer 290 inserted at the protection layer 280. The transparent conducting layer 290 is configured to electrically connect to the source electrode 260, the drive circuit board 600, the drain electrode 270, and the drive circuit board 600.

The present application further provides a display device. The display device provided in this embodiment has substantially the same technical features as the display device of the above embodiment, and the difference is:

As shown in FIG. 3, the display device includes a display panel 100, a first switch optical sensor 200, a second switch optical sensor 300, a signal processor (not shown), a control assembly (not shown), and a drive circuit board 600. The display panel 100 has a display area (not shown) and a non-display area (not shown). As shown in FIG. 2, the first switch optical sensor 200 is disposed at the non-display area of the display panel 100, and is mainly configured to convert the environmental light intensity into the first electrical signal. Correspondingly, the second switch optical sensor 300 is disposed at the display area of the display panel 100, and is mainly configured to convert the light intensity inside the display and the environmental light intensity into a second electrical signal.

It should be noted that, as shown in FIG. 2, the non-display area of the display panel 100 is usually the edge portion of the display panel 100, and the display area is usually the middle portion of the display panel 100. Of course, in practice, the positional relationship between the non-display area and the display area is not limited to this. Specifically, in the embodiment, the first switch optical sensor is a thin film transistor device, and correspondingly, the second switch optical sensor is also a thin film transistor device.

In this embodiment, the signal processor is primarily configured to receive, process, and feed back the first electrical signal and the second electrical signal. The control assembly (not shown) can automatically regulate the display brightness of the display panel 100 according to the first electrical signal and the difference between the second electrical signal and the first electrical signal. Understandably, both the first switch optical sensor 200 and the second switch optical sensor 300 act as optical sensors, which can simultaneously monitor the environmental light intensity and the light intensity inside the display, and by ensuring a balanced status between the environmental light intensity and the light intensity inside the display, and there will be no problem of excessive energy consumption or visual acuity caused by one of them being too dark or too bright. In addition, the drive circuit board 600 is electrically connected to a control assembly (not shown).

As shown in FIG. 3, the first switch optical sensor 200 and the second switch optical sensor 300 each includes a channel layer 240, a source electrode 260, and a drain electrode 270. In the present embodiment, the channel layer 240 has photosensitivity. The source electrode 260 and the drain electrode 270 are not in contact with each other and are connected to the drive circuit board 600, and are disposed above the channel layer 240.

In addition, the channel layer 240 corresponds to a portion between the source electrode 260 and the drain electrode 270 to form a conductive channel 400; the first switch optical sensor 200 and the second switch optical sensor 300 are electrically connected to the drive circuit board 600, so that the channel layer 240 can not only collect light intensity to generate photoconductive current, but also conduct the generated photoconductive current to the drive circuit board 600 via the source electrode 260 and the drain electrode 270. Taking the first switch optical sensor 200 as an example, the environmental light intensity can be judged according to the magnitude of the photoconductive current, and the brightness of the display screen can be regulated by the control assembly of the display device by changing the output power of the backlight module to save energy and protect the human eyes.

The present application also provides a method for automatically regulating the screen brightness of the display device. Wherein, as shown in FIG. 3, the display device includes a control assembly (not shown), a display panel 100, a first switch optical sensor 200, and a second switch optical sensor 300. Specifically, the display panel 100 has a display area and a non-display area. The first switch optical sensor 200 is disposed at the non-display area of the display panel 100, and the second switch optical sensor 300 is disposed at the display area of the display panel 100.

Specifically, in this embodiment, both the first switch optical sensor 200 and the second switching optical sensor are optical sensors modified by the thin film transistor device. In other words, in the embodiment, the display panel 100 includes a black matrix (not shown), and the black matrix defines therein avoidance notches (not shown) corresponding to light sensing portions of the first switch optical sensor 200 and the second switch optical sensor 300, that is, the first switch optical sensor 200 is a first thin film transistor device 200 that does not need to be shielded by the black matrix, and the second switch optical sensor 300 is a second thin film transistor device 300 that does not need to be shielded by the black matrix.

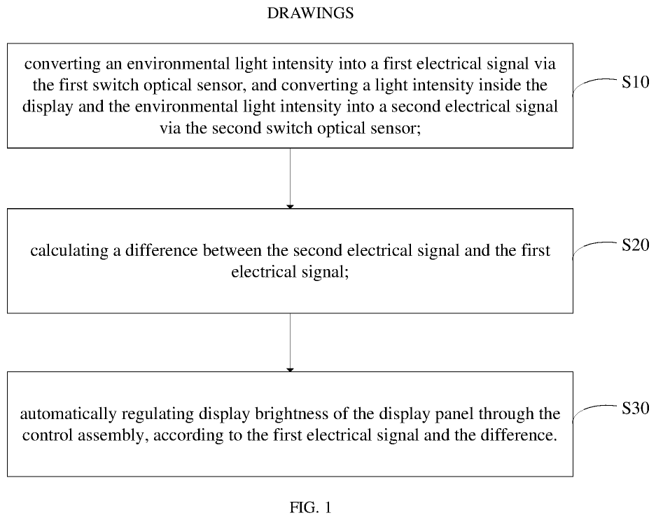

As shown in FIG. 1, the method includes:

S10: converting an environmental light intensity into a first electrical signal via the first switch optical sensor 200, and converting a light intensity inside the display and the environmental light intensity into a second electrical signal via the second switch optical sensor 300. In order to simplify the regulation step, generally, the first electrical signal and the second electrical signal are converted simultaneously.

S20: calculating a difference between the second electrical signal and the first electrical signal.

Specifically, in this embodiment, the step further includes: respectively receiving the first electrical signal and the second electrical signal via the signal processor; and

calculating the difference between the second electrical signal and the first electrical signal.

Finally, feeding back the first electrical signal and the difference between the second electrical signal and the first electrical signal to the control assembly.

Of course, in fact, the light intensity received by the second switch optical sensor 300 can be directly compared with the light intensity received by the first switch optical sensor 200.

S30: automatically regulating a display brightness of the display panel according to the first electrical signal and the difference between the first electrical signal and the second electrical signal.

It can be understood from the above that, specifically, in this embodiment, the working principle of the overall structure of the display device and the automatically regulating of the screen brightness of the display device are as follows:

The display device utilizes the photosensitive characteristics of the conductive channel 400 of the conventional TFT device, the first switch optical sensor 200 and the second switch optical sensor 300 which are not shielded by the black matrix are directly formed in the edge portion and the middle portion of the display panel 100 without separately mounting the optical sensor. And the first switch optical sensor 200 located at the edge portion is used to convert the environmental light intensity into the first electrical signal, and simultaneously, the second switch optical sensor 300 located in the middle portion is used to convert the environmental light intensity and the light intensity inside the display into the second electrical signal, and the first electrical signal and the second electrical signal are calculated via the signal processor, and the related signal is fed back to the control assembly, thereby the control assembly can automatically regulate the brightness of display screen according to the first electrical signal and the difference between the first electrical signal and second first electrical signal, so as to ensure that the environmental light intensity and the light intensity inside the display reach a balanced status, which greatly saves energy consumption and reduces the probability of myopia of teenager eyes.

The aforementioned embodiments are only optional embodiments of the present application, and should not be regarded as being limitation to the present application. Any modification, equivalent replacement, improvement, and so on, which are made within the spirit and the principle of the present application, should be included in the protection scope of the present application.

What is claimed is:

1. A display device, comprising a control assembly and a display panel having a display area and a non-display area; and the display device further comprising:
a first switch optical sensor, disposed at the non-display area of the display panel and configured to convert an environmental light intensity into a first electrical signal; and
a second switch optical sensor, disposed at the display area of the display panel and configured to convert a light intensity inside the display and the environmental light intensity into a second electrical signal;
wherein, the control assembly is configured to automatically regulate display brightness of the display panel according to the first electrical signal and a difference between the second electrical signal and the first electrical signal.

2. The display device of claim 1, wherein the display device further comprises a signal processor configured to receive, process, and feed back the first electrical signal and the second electrical signal.

3. The display device of claim 1, wherein the display panel comprises a black matrix, and the black matrix defines therein avoidance notches corresponding to light sensing portions of the first switch optical sensor and the second switch optical sensor.

4. The display device of claim 1, wherein the first switch optical sensor and the second switch optical sensor are manufactured by a four-layer mask process.

5. The display device of claim 1, wherein the display device further comprises a drive circuit board electrically connected to the control assembly; the first switching optical sensor and the second switching optical sensor each comprise:
a channel layer, which is light sensitive and configured to collect light intensity and to generate a photoconductive current;
a source electrode, connected to the drive circuit board and disposed above the channel layer; and
a drain electrode, connected to the drive circuit board and disposed above the channel layer;
the channel layer forms therein a conductive channel corresponding to a portion between the source electrode and the drain electrode; the first switch optical sensor and the second switch optical sensor are electrically connected to the drive circuit board.

6. The display device of claim 5, wherein the first switch optical sensor and the second switch optical sensor each further comprises:
a substrate;
a switch gate electrode, disposed at the substrate; and,
an insulation layer, disposed at the substrate and configured to protect the switch gate electrode and to separate the channel layer from the switch gate electrode.

7. The display device of claim 6, wherein the first switch optical sensor and the second switch optical sensor each further comprises:
a doped layer, disposed above the channel layer and configured to reduce contact resistances between the channel layer and the source electrode and between the channel layer and the drain electrode.

8. The display device of claim 6, wherein the insulation layer is provided with a protection layer;
the protection layer surrounds the channel layer, the doped layer, the source electrode, and the drain electrode from peripheries thereof, and the protection layer is provided with an opening configured to adapt to the conductive channel.

9. A display device, comprising:
a display panel, having a display area and a non-display area;
a first switch optical sensor, disposed at the non-display area of the display panel and configured to convert an environmental light intensity into a first electrical signal;
a second switch optical sensor, disposed at the display area of the display panel and configured to convert a light intensity inside the display and the environmental light intensity into a second electrical signal;
a signal processor, configured to receive, process, and feed back the first electrical signal and the second electrical signal;
a control assembly, configured to automatically regulate display brightness of the display panel according to the first electrical signal and a difference between the second electrical signal and the first electrical signal;
the display device further comprises:
a drive circuit board, configured to electrically connect with the control assembly;
the first switch optical sensor and the second switch optical sensor each comprises:
a channel layer, which is light sensitive and configured to collect light intensity and generate a photoconductive current;
a source electrode, connected to the drive circuit board and disposed above the channel layer; and
a drain electrode, connected to the drive circuit board and disposed above the channel layer;
the channel layer forms therein a conductive channel corresponding to a portion between the source electrode and the drain electrode; the first switch optical sensor and the second switch optical sensor are electrically connected to the drive circuit board.

10. The display device of claim 9, wherein the first switch optical sensor and the second switch optical sensor each further comprises:
a substrate;
a switch gate electrode, disposed at the substrate; and,
an insulation layer, disposed at the substrate and configured to protect the switch gate electrode and to separate the channel layer from the switch gate electrode.

11. The display device of claim 10, wherein the first switch optical sensor and the second switch optical sensor each further comprises:
a doped layer, disposed above the channel layer and configured to reduce contact resistances between the channel layer and the source electrode and between the channel layer and the drain electrode.

12. The display device of claim 11, wherein the insulation layer is provided with a protection layer;
the protection layer surrounds the channel layer, the doped layer, the source electrode, and the drain electrode from peripheries thereof; the protection layer is provided with an opening configured to adapt to the conductive channel.

13. The display device of claim 9, wherein the first switch optical sensor and the second switch optical sensor are thin film transistor devices.

14. A method for automatically regulating screen brightness of a display device, the display device comprising:
a control assembly;
a display panel, having a display area and a non-display area;
a first switch optical sensor, disposed at the non-display area of the display panel; and
a second switch optical sensor, disposed at the display area of the display panel; and
wherein the method comprises:
converting an environmental light intensity into a first electrical signal via the first switch optical sensor, and converting a light intensity inside the display and the environmental light intensity into a second electrical signal via the second switch optical sensor;
calculating a difference between the second electrical signal and the first electrical signal;
automatically regulating display brightness of the display panel through the control assembly, according to the first electrical signal and the difference.

15. The method of claim 14, wherein the display device further comprises a signal processor; and the step of calculating a difference between the second electrical signal and the first electrical signal comprises:
respectively receiving the first electrical signal and the second electrical signal via the signal processor; and
calculating the difference between the second electrical signal and the first electrical signal.

16. The method of claim 14, wherein the display panel comprises a black matrix, and the black matrix defines therein avoidance notches corresponding to light sensing portions of the first switch optical sensor and the second switch optical sensor.

17. The method of claim 14, wherein the first switch optical sensor and the second switch optical sensor are thin film transistor devices.
